(19) United States
(12) Patent Application Publication
(10) Pub. No.: US 2016/0216610 A1
(43) Pub. Date: Jul. 28, 2016

(54) EXPOSURE APPARTUS AND RETICLE FORMING METHOD THEREOF

(71) Applicants: JEUNGHWAN PARK, SUWON-SI (KR); SUNGHOON KIM, SEONGNAM-SI (KR); JAE-IL LEE, HWASEONG-SI (KR)

(72) Inventors: JEUNGHWAN PARK, SUWON-SI (KR); SUNGHOON KIM, SEONGNAM-SI (KR); JAE-IL LEE, HWASEONG-SI (KR)

(21) Appl. No.: 14/979,864

(22) Filed: Dec. 28, 2015

(30) Foreign Application Priority Data
Jan. 22, 2015 (KR) 10-2015-0010612

(51) Int. Cl. G03F 7/20; G03F 1/76; G03F 1/20

(52) U.S. Cl. CPC G03F 7/7015; G03F 1/20; G03F 1/76

(57) ABSTRACT

A reticle of an exposure apparatus includes a reticle pattern that includes respective patterns of core areas of at least two chips, respective patterns of peripheral areas of the at least two chips, and a scribe lane pattern. With respect to the patterns of each of at least one pair of the chips, the patterns of the core areas of the chips are adjacent to each other. Alternatively, or in addition, with respect to the patterns of each of at least one pair of the chips, the patterns of the peripheral areas of those chips are adjacent to each other. In the case of the patterns of the core areas of two of the chips and/or the patterns of the peripheral areas of the chips, the patterns are disposed directly across from each other on opposite sides of the scribe lane pattern.

### PRIORITY STATEMENT

This U.S. non-provisional patent application claims priority under 35 U.S.C. §119 is made to Korean Patent Application No. 10-2015-0010612 filed Jan. 22, 2015, the entire contents of which are hereby incorporated by reference.

### BACKGROUND

The inventive concept described herein relates to a reticle, to the fabricating of a reticle, to an exposure apparatus including a reticle, and to a method of fabricating a semiconductor device using an exposure apparatus.

In general, the manufacturing a semiconductor device includes such processes as a deposition process, an ion injection process, a photolithography process, a rinsing process, and a polishing process. A plurality of semiconductor devices may be formed on a wafer by iteratively performing such processes.

Among the processes, the photolithography process may entail a selective removal of a film deposited on the wafer to form a fine pattern. More specifically, a typical photolithography process includes a photoresist coating process for forming a photoresist film on a lower layer covering a wafer, an exposure process for reducing the image of a pattern of a photomask or “reticle” (corresponding to a desired circuit pattern) and exposing the photoresist film to the reduced image of the circuit pattern, a developing process for selectively removing the exposed or non-exposed portions of the photoresist film, an etching process of etching the lower film using the resulting photoresist film pattern as an etch mask resulting in a transcribing of the reticel pattern onto the wafer in the form of a circuit pattern, and a stripping process for removing any remaining photoresist film.

### SUMMARY

According to one aspect of the inventive concept there is provided a reticle for use in a lithographic exposure process, comprising a substrate and a reticle pattern borne by the substrate, and in which the reticle pattern comprises patterns of core areas of at least two chips, patterns of peripheral areas of the at least two chips, and a scribe lane pattern separating the patterns of the chips from one another, and in which the patterns of the core areas of two of the chips are disposed directly across from each other on opposite sides of the scribe lane pattern and/or the patterns of the peripheral areas of two of the chips are disposed on opposite sides of a scribe lane as disposed directly across from each other.

According to another aspect of the inventive concept, there is provided a method of manufacturing a reticle, comprising forming a photoresist layer on a substrate, forming a photoresist pattern by exposing and developing the photoresist layer, and carrying out an etch process using the photoresist pattern as an etch mask, and in which the forming of the photoresist pattern and the etch process form a reticle pattern comprising patterns of core areas of at least two chips, patterns of peripheral areas of the at least two chips, and a scribe lane pattern separating the patterns of the chips from one another, and in which the patterns of the core areas of two of the chips are disposed directly across from each other on opposite sides of the scribe lane pattern and/or the patterns of the peripheral areas of two of the chips are disposed on opposite sides of a scribe lane as disposed directly across from each other.

According to still another aspect of the inventive concept, there is provided

an exposure apparatus comprising a light source, a reticle comprising a substrate and having a reticle pattern borne by the substrate and supported in the exposure apparatus so as to be illuminated with light emitted from the light source whereby an image of the reticle pattern is transmitted, reduction-projection optics that reduces the size of the image of the reticle pattern transmitted by the reticle and projects the reduced image of the reticle pattern along an optical axis, and a wafer stage configured to support a wafer in the path of the optical axis such that a layer on the wafer can be exposed to the image of the reticle pattern projected by the reduction-projection optics, and in which the reticle pattern includes patterns of core areas of at least two chips, patterns of peripheral areas of the at least two chips, and a scribe lane pattern separating the patterns of the chips from one another, the patterns of the core areas of two of the chips are disposed directly across from each other on opposite sides of the scribe lane pattern and/or the patterns of the peripheral areas of two of the chips are disposed on opposite sides of a scribe lane as disposed directly across from each other.

### BRIEF DESCRIPTION OF THE FIGURES

The inventive concept will become more apparent from the following detailed description made with reference to the attached figures, wherein like reference numerals designate like parts or features throughout unless otherwise specified, and wherein

FIG. 1 is a schematic diagram of an example of an exposure apparatus according to the inventive concept;

FIG. 2 is a schematic plan view of an example of a reticle according to the inventive concept;

FIG. 3 is a schematic plan view of another example of reticle according to the inventive concept;

FIG. 4 is a schematic plan view of still another example of reticle according to the inventive concept;

FIG. 5 is a conceptual diagram illustrating a leveling of an exposure apparatus according to the inventive concept;

FIG. 6 is a perspective view of a memory block of a cell array of a memory chip that may be fabricated using a reticle in accordance with the inventive concept;

FIG. 7 is a perspective view of another memory block that may be fabricated using a reticle in accordance with the inventive concept;

FIG. 8 is flowchart of a semiconductor device manufacturing method according to the inventive concept; and

FIG. 9 is a block diagram of a mobile device having a chip that may be fabricated using a reticle in accordance with the inventive concept.

### DETAILED DESCRIPTION

Examples of the inventive concept will be described in detail with reference to the accompanying drawings. The inventive concept, however, may be practiced in various different forms, and should not be construed as being limited only to the illustrated examples. Rather, these examples are provided so that this disclosure will be thorough and complete, and will fully convey the inventive concept to those skilled in the art. Accordingly, known processes, elements, and techniques are not described with respect to some of the examples of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

In the description below, it will be understood that when an element such as a layer, region, substrate, plate, or member is referred to as being “on” another element, it can be directly on the other element or intervening elements may be present. In contrast, the term “directly” means that there are no intervening elements.

Also, the examples of the inventive concept may be described with reference to cross-sectional views and/or plan views. In the drawings, the thickness of layers and regions may be exaggerated for effective description of the technical contents. Therefore, exemplary illustration may be modified according to manufacturing techniques and/or allowable error, etc. Thus, the inventive concept may also encompass changes in form produced according to a manufacturing process, not limited to the specific forms shown. For example, a right-angled etching area may have a rounded form or a form having a predetermined curvature. Thus, the drawings do not limit regions or elements of a device according to the inventive concept as having the particular form illustrated.

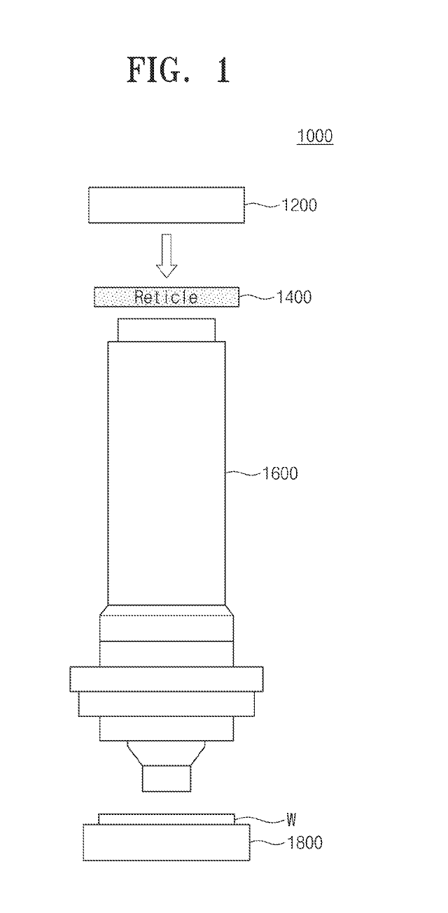

An example of an exposure apparatus according to the inventive concept FIG. 1 will now be described in detail with reference to FIG. 1.

The exposure apparatus 1000 may include a light source for exposure 1200, a reticle 1400, a reduction projection optical device 1600, and a wafer stage 1800. The exposure apparatus 1000 may further include a height sensor for measuring height and inclination of a wafer (W) surface.

The light source 1200 may emit light (denoted by the arrow) for transcribing an image of a pattern of the reticle 1400 onto a wafer in a photolithography process. The light source 1200 may be an ultraviolet light source. For example, the light source may comprise a KrF (234 nm) light source or an ArF (193 nm) light source. Although not shown, the light source 1200 may also include a collimator. The collimator may convert ultraviolet light emitted by the ArF (193 nm) light source into parallel rays of light. The parallel light rays of light may be transmitted to the reticle 1400. The collimator may include a dipole or quadurple aperture for increasing the depth of a focus of the ultraviolet light.

The reticle 1400 has a pattern (which may be referred to as a “mask pattern” or a “reticle pattern”) that is designed by a user for transcription to a wafer W in the photolithography process. Examples of the reticle 1400 will be described in more detail later on.

The reduction projection optical device 1600 may align a desired portion of the wafer W (corresponding to a “shot” of the exposure apparatus) with the pattern of the reticle 1400 in the photolithography process. To this end, the reduction projection optical device 1600 may include an object lens. The object lens may focus the ultraviolet light onto the wafer W. The size of shot of the exposure apparatus 1000 may depend on the diameter of the object lens. For example, the size of a shot may be a quarter of the size of the reticle pattern.

The wafer stage 1800 supports the wafer W on which a pattern corresponding to that of the reticle is transcribed in the photolithography process.

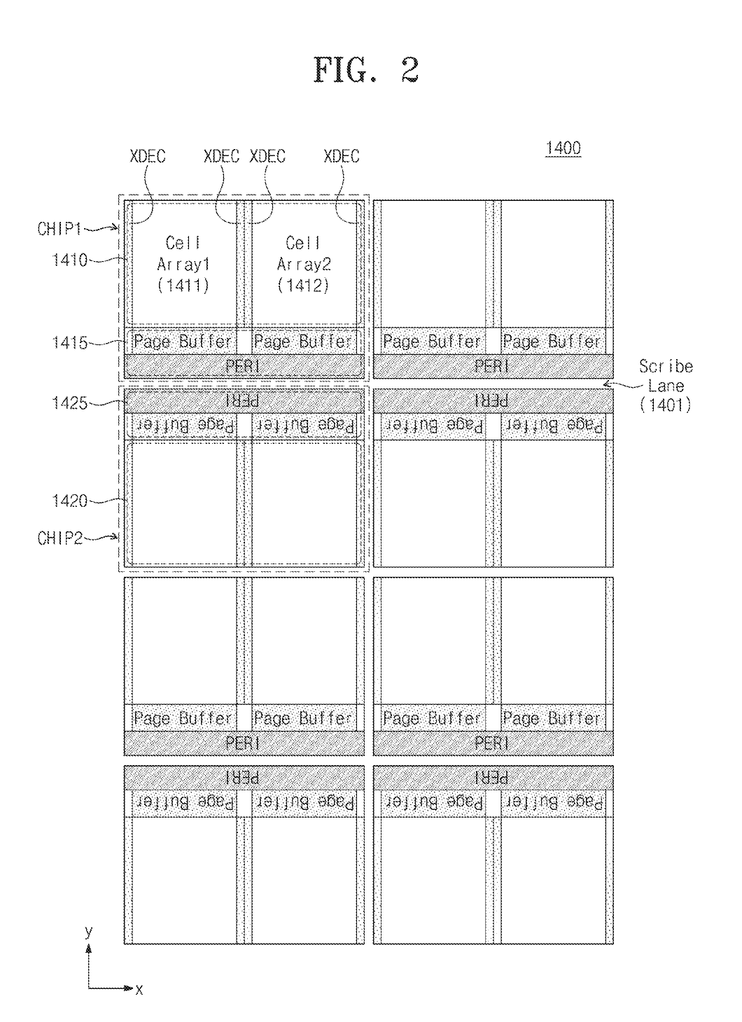

An example of the reticle 1400 according to the inventive concept will now be described with reference to FIG. 2. In this example, the reticle 1400 is designed for use in forming patterns of eight chips with each chip including two cell arrays. However, the number of chips whose patterns are to be formed using a reticle according to the inventive concept is not limited to the specific numbers (e.g., eight) shown and described throughout the disclosure. Therefore, patterns of the reticle 1400 may be referred to hereinafter as “chip patterns”, respectively.

A first chip pattern and a second chip pattern may be symmetrical with respect to part of a first scribe lane of scribe lane pattern 1401 extending lengthwise in an x-axis direction. For example, the first chip pattern and the second chip pattern may have point symmetry with respect to a point within the scribe lane pattern 1401. For ease of description, though, a pattern of the reticle 1400, i.e., the mask or “reticle pattern” may be described using terms corresponding to features of actual chips to be formed using the reticle. Here, the scribe lane pattern 1401 may be a line(s) along which chips are separated from each. In particular, a core area 1410 of the first chip CHIP1 and a core area 1420 of the second chip CHIP2 may be disposed adjacent to and face each other across the aforementioned firs scribe lane extending lengthwise in an x-axis direction. As illustrated in FIG. 2, each of the core areas 1410 and 1420 may include cell arrays formed of a plurality of memory blocks and address decoders XDEC. A peripheral area 1415 of the first chip CHIP1 and a peripheral area 1425 of the second chip CHIP2 may be disposed adjacent to and face each other across the scribe lane pattern 1401. As illustrated in FIG. 2, each of the peripheral areas 1415 and 1425 may include a page buffer for reading or storing data from or at the a cell array and any other peripheral circuit PERI.

As illustrated in FIG. 2, chips may be disposed to have line symmetry about one scribe lane, of scribe lane pattern 1401, extending lengthwise in a y-axis direction perpendicular to the x-axis direction.

Furthermore, each of the first and second chips CHIP1 and CHIP2 of the example of the reticle 1400 illustrated in FIG. 2 has a 2-mat structure including two cell arrays (e.g., 1411 and 1422). However, the scope and spirit of the inventive concept is not be limited thereto. For example, a chip of the inventive concept may have a 1-mat structure or an m-mat structure (m being an integer of 3 or more).

In the example of the reticle 1400 illustrated in FIG. 2, each of the first and second chips CHIP1 and CHIP2 includes two cell arrays 1411 and 1412 formed of a plurality of memory blocks and address decoders XDEC disposed at both sides of each cell array. However, the scope and spirit of the inventive concept is not be limited thereto. Address decoders of the inventive concept may be disposed at various locations in the chips.

In the example of the reticle 1400 illustrated in FIG. 2, page buffers are disposed at the bottoms of the cell arrays 1411 and 1412. However, the scope and spirit of the inventive concept is not be limited thereto. Page buffers of the inventive concept may be disposed at various locations in the chips.

In a reticle of the inventive concept, Test Element Groups (TEGs) may be disposed at various locations depending on specific applications. A TEG may include test elements that are formed using the same processes as a normal die for quality control during processes and may be disposed in the scribe lane pattern 1401.

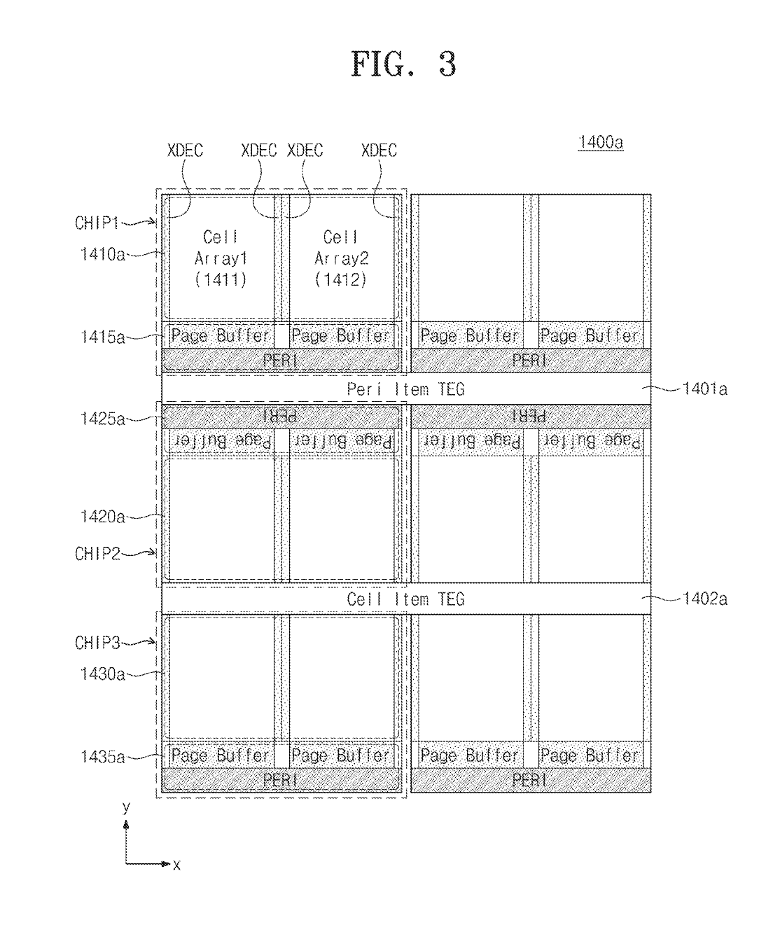

Another example of a reticle 1400a according to the inventive concept is illustrated in FIG. 3.

Referring to FIG. 3, the scribe lane pattern of the reticle 1400a may include a first scribe lane 1401a where a test element group for a peripheral area is disposed and a second scribe lane 1402a where a test element group for a cell area is disposed.

In this example, the first scribe lane pattern 1401a is interposed between a peripheral area 1415a of a first chip CHIP1 and a peripheral area 1425a of a second chip CHIP2.

Likewise, in this example, the second scribe line pattern 1402a is interposed between a peripheral area 1420a of the second chip CHIP2 and a core area 1430a of a third chip CHIPS.

The reticle 1400a according may include an alignment key. Here, the alignment key of the reticle 1400a may be used with an alignment key (not shown) on a wafer to determine whether the wafer is aligned with the exposure apparatus 1000. More specifically, a state of alignment or mis-alignment between the alignment key of the reticle 1400a and the alignment key of the wafer may be discerned to determine whether the wafer is aligned with the exposure apparatus 1000

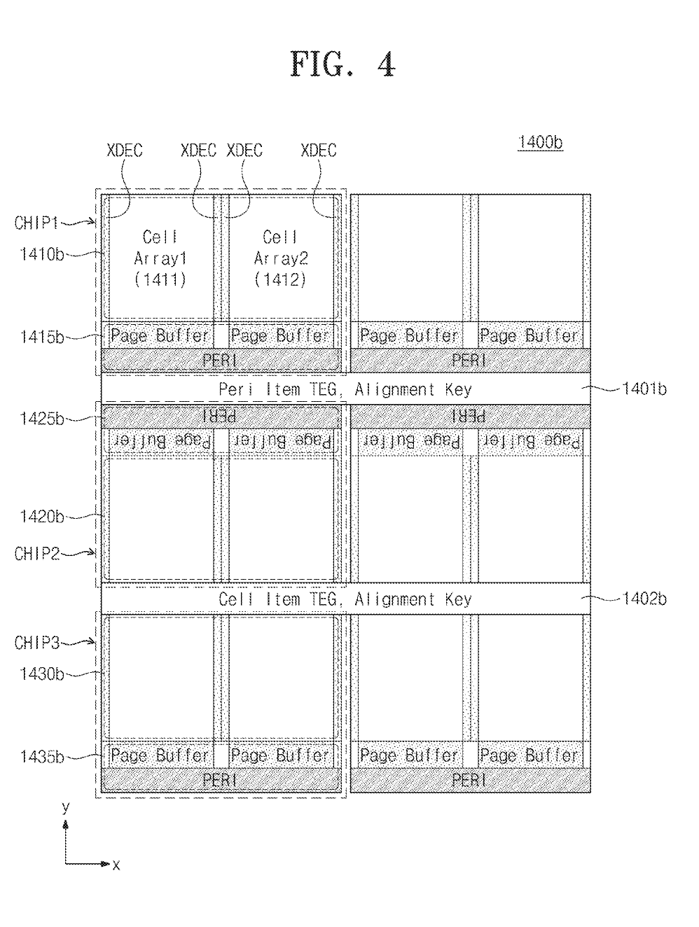

Still another example of a reticle 1400b according to the inventive concept is shown in FIG. 4.

The reticle 1400b may include a first scribe lane 1401b where a test element group for a peripheral area and an alignment key are disposed and a second scribe line 1402b where a test element group for a cell area and an alignment key are disposed.

In the example of the reticle 1400b illustrated in FIG. 4, the first scribe lane 1401b and the second scribe lane 1402b both include alignment keys. However, the scope and spirit of the inventive concept is not limited thereto. For example, only one of the first scribe lane 1401b and the second scribe lane pattern 1402b may include an alignment key.

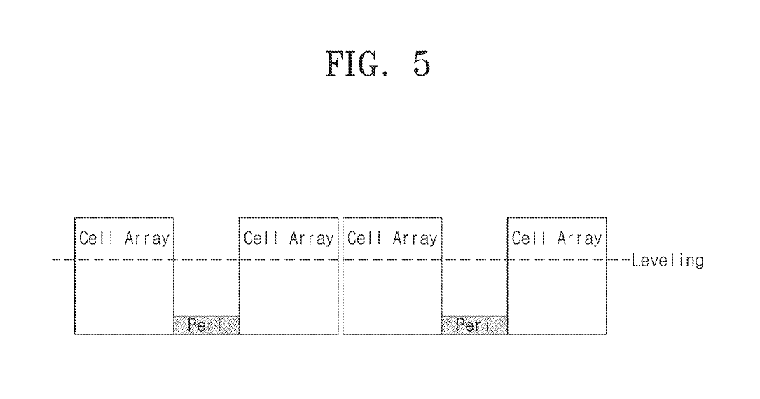

FIG. 5 illustrates a leveling operation associated with an exposure apparatus 1000 according to the inventive concept. For an image of a reticle pattern to be transcribed precisely onto a wafer, the wafer must be positioned within a depth of focus of the reduction projection lens of the exposure apparatus during the exposure process. Also, at this time, the focus plane must be level (i.e., not tilted) with respect to the optical axis of the reduction projection lens. That is, the reduction projection lens and the wafer must be in what may be referred to as a mutually vertical state. A generally automated operation of making the reduction projection optical device 1600 and the wafer in a mutually vertical state, in preparation for the exposure process, is referred to as “leveling”. Such leveling is typically carried out by examining the topography of the layer on the wafer to be exposed and setting the position of the focal plane such that the regions of the layer to be exposed all fall within the depth of focus to the greatest extent possible. Sometimes the focal plane may be tilted as a result of the leveling operation.

Referring to FIG. 5, the peripheral areas face each other, and the cell array areas face each other, thereby preventing the leveling operation form creating a tilt in the focal plane. A tilt in the focal plane could otherwise, as described above, result in a focus difference between different regions (upper and lower regions or left and right regions) of a shot. According to an aspect of the inventive concept, cell array areas having the same stack structure may be disposed at upper and lower portions of a shot (left and right regions in FIG. 5), thereby ensuring that an optimal leveling operation takes place.

In particular, in a reticle according to the inventive concept, with respect to the patterns of each of at least one pair of the chips, the patterns of the core areas of the chips are adjacent to each other. Alternatively, or in addition, with respect to the patterns of each of at least one pair of the chips, the patterns of the peripheral areas of those chips are adjacent to each other. In the case of the patterns of the core areas of two of the chips and/or the patterns of the peripheral areas of the chips, the patterns are disposed directly across from each other on opposite sides of the scribe lane pattern. In the case of a reticle for use in fabricating a semiconductor memory device, the pattern of a core area may include that of a memory cell array and an address decoder, and the pattern of a peripheral area may include that of an input/output circuit including a page buffer. In any case, the patterns of peripheral areas of the reticle and the patterns of the core areas have a symmetry, in light of the leveling operation, for reasons that are clear from the description above but will be described in even more detail later on.

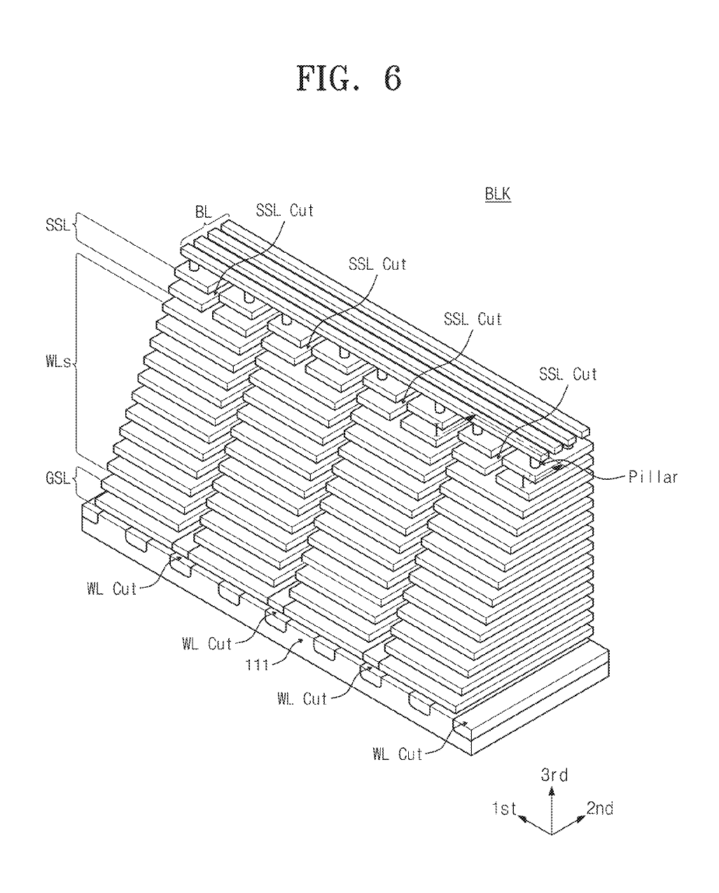

FIG. 6 shows a memory block of a cell array of a memory chip that can be fabricated according to the inventive concept. Referring to FIG. 6, four sub blocks are formed on a substrate. The sub blocks may be formed by sequentially forming and etching layers on a substrate to form at least ground selection line GSL, a plurality of word lines, and at least one string selection line SSL each being plate-shaped. Each string selection line SSL may have discrete sections separated by a string selection line cut SSL Cut. However, the scope and spirit of the inventive concept is not be limited thereto. That is, the string selection lines may be contiguous in each sub block, i.e., the string selection line cuts SSL_Cut are optional.

Furthermore, at least one plate-shaped dummy word line may be formed between the ground selection line GSL and the word lines. Alternatively, at least one plate-shaped dummy word line may be formed between the word lines and the string selection line SSL.

The etching of layers on the substrate may include forming word line cuts WL Cut dividing the sub blocks from one another. Each word line cut may extend into the substrate so as to define a recess in an upper surface of the substrate and may contain a common source line CSL. In one example, the common source lines CSL in the word line cuts are electrically interconnected. A cell string may be formed by forming a pillar through the at least one string selection line SSL, the word lines, and the at least one ground selection line GSL, and forming a bit line connected to the pillar.

In FIG. 6, each structure between adjacent word line cuts is a sub block. However, devices having other operative configurations may be fabricated according to the inventive concept. For example, each structure between a word line cut and a string selection line cut may be a sub block. The memory block BLK may also have a merged word line structure in which two word lines are in effect merged.

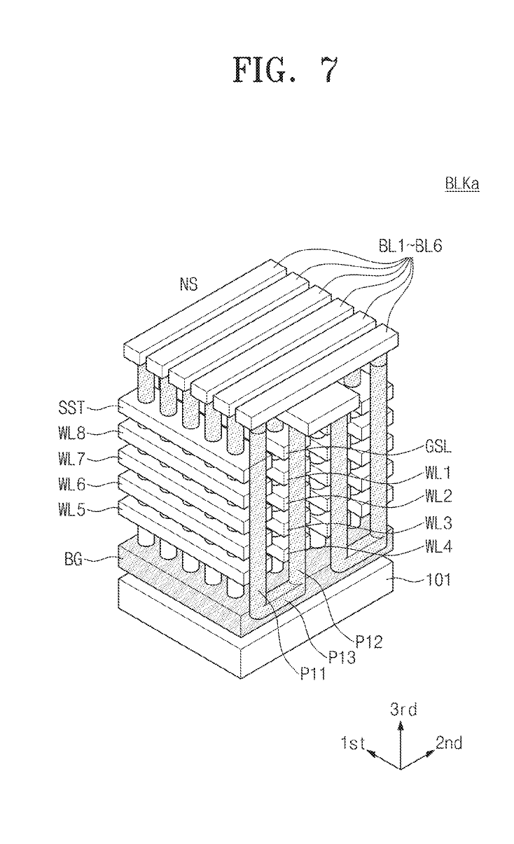

FIG. 7 illustrates another example of a memory block which may be fabricated according to the inventive concept. For ease of illustration, four word line layers are shown in the figure.

The memory block BLKb may have a PBiCS (pipe-shaped bit cost scalable) structure in which lower ends of adjacent memory cells connected in series are connected through pipes. In such a structure the memory block contains m-by-n strings NS (n and m being a natural number).

In the example illustrated in FIG. 7, m=6 and n=2. Each string NS contains memory cells MC1 through MC8 that are connected in series. First upper ends of the memory cells MC1 through MC8 may be connected to string selection transistors SST, second upper ends thereof may be connected to ground selection transistors GST, and lower ends thereof may be connected through pipes.

In each string NS, memory cells may be formed to be stacked on a plurality of semiconductor layers. Each string NS may contain a first pillar P11, a second pillar P12, and a pillar connection portion P13 connecting the first and second pillars P11 and P12. The first pillar P11 may be connected to a bit line (e.g., BL1) and the pillar connection portion P13 and may extend through a string selection line SSL and word lines WL5 through WL8. The second pillar P12 may be connected to a common source line CSL and the pillar connection portion P13 and may extend through a ground selection line GSL and word lines WL1 through WL4. As illustrated in FIG. 6, each string NS may comprise a U-shaped pillar.

In the illustrated example, a back-gate BG is formed on substrate 101, and the pillar connection portion P13 is embedded in the back-gate BG. The back-gate BG may be used in common in the block BLKa. The back-gate BG may be separated from a back-gate of another block.

As is clear from the descriptions above, a three dimensional (3D) memory array may be formed according to the inventive concept, i.e., using a photolithography process employing a reticle according to the inventive concept. The 3D memory array is monolithically formed in one or more physical levels of arrays of memory cells having an active area disposed above a silicon substrate and circuitry associated with the operation of those memory cells, whether such associated circuitry is above or within such substrate. The term “monolithic” means that layers of each level of the array are directly deposited on the layers of each underlying level of the array.

The 3D memory array may include vertical NAND strings that are vertically oriented such that at least one memory cell is located over another memory cell. The at least one memory cell may comprise a charge trap layer.

The following patent documents, which are hereby incorporated by reference, describe suitable configurations for three-dimensional memory arrays, in which the three-dimensional memory array is configured as a plurality of levels, with word lines and/or bit lines shared between levels: U.S. Pat. Nos. 7,679,133; 8,553,466; 8,654,587; 8,559,235; and US Pat. Pub. No. 2011/0233648.

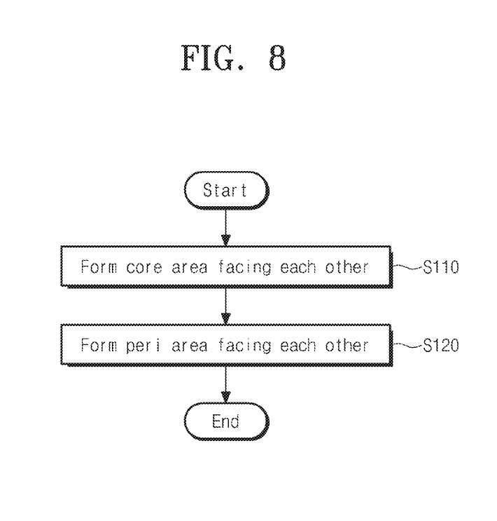

A method of manufacturing a reticle according to the inventive concept is illustrated in FIG. 8. Referring to FIG. 8, (reticle) patterns of core areas of different chips may be formed to face each other across a scribe lane pattern (step S110) and/or (reticle) patterns of peripheral areas of different chips may be formed to face each other across the scribe lane pattern (step S120). A test element group for a peripheral area may be formed between the patterns of the peripheral areas. A test element group for a core area may be formed between the patterns of the core areas.

The patterns of the core areas and/or the peripheral areas may be formed as follows. A substrate may be prepared. For example, the substrate may be a transparent substrate. In this case, the transparent substrate may be a glass or plastic susbtrate. A mask layer and photoresist may be sequentially formed on the substrate. The mask layer may include chrome that is formed using a sputtering or electric plating process. The photoresist may be formed using a spin coating process. Next, the photoresist is exposed. For example, the photoresist may be exposed to electron beams. The beams may be provided by an electronic gun. Subsequently, the exposed layer of photoresist is patterned by a developing process. The resulting layer of photoresist pattern exposes a portion of the mask layer. Next, a mask pattern, i.e., the reticle pattern, is formed using the photoresist pattern as an etch mask. The reticle pattern may have the minimum feature size. Also, at about this time, the photoresist pattern is removed.

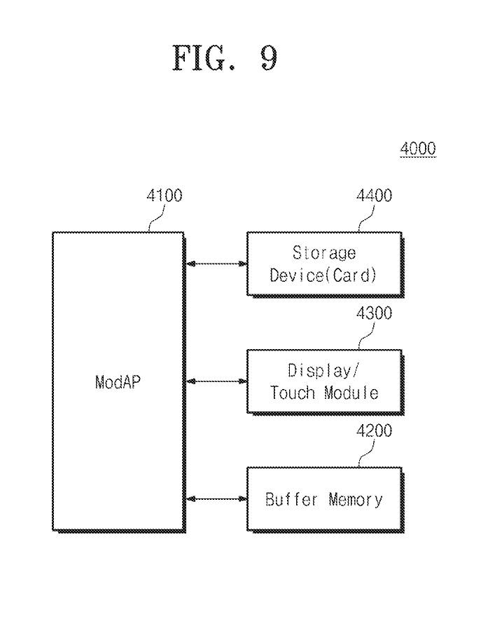

FIG. 9 illustrates an example of a mobile device having a chip of a type that can be fabricated according to the inventive concept.

Referring to FIG. 9, the mobile device 4000 may include an integrated processor (ModAP) 4100, a buffer memory 4200, a display/touch module 4300, and a storage device 4400.

The integrated processor 4100 may control an overall operation of the mobile device 4000 and wireless/wire communications with an external device. The buffer memory 4200 may store data required for performing a processing operation of the mobile device 4000. The display/touch module 4300 may display data processed by the integrated processor 4100 or receive data. To this end, the display/touch module 4300 may comprise a touch panel. The storage device 4400 may store user data. The storage device 4400 may be, but is not limited to, a memory card, an eMMC, an SSD, or an UFS device. The storage device 4400 may have a memory chip fabricated according to the inventive concept, i.e., using any of the reticles according to the inventive concept.

In a method of manufacturing a semiconductor according to the inventive concept, the reticle is loaded onto a reticle stage of an exposure apparatus (refer to FIG. 2) such as a scanner or a stepper. A target pattern, corresponding to the reticle pattern, is then formed on a substrate, e.g., a wafer, using the exposure apparatus. The target pattern may comprise any of various patterns of the semiconductor memory devices illustrated in and described with reference to FIGS. 6 and 7, and may be an end pattern of a semiconductor device.

In general, each of the target patterns (corresponding to shots in an exposure process using a stepper, for exmple) is to have a shape similar to that of the reticle pattern of a macro-line width. However, the shape of certain ones of the target patterns may differ from that of the reticle pattern having a micro-line width due to small variations in the process parameters among the respective exposure and etching processes for forming the target patterns, respectively. In particular, most but not all of the target patterns may have a micro-line width. Accordingly, the light sources that illuminate a reticle to form target patterns may account for variations in the process parameters to ensure that all the target patterns have a desired micro-line width. Examples of exposure apparatus that can illumintate the reticle to ensure better uniformity in the target patterns, and to which the inventive concept may also be applied, include a VSB (Variable Shaped Beam) mask writer and an MBMW (Multi-Beam Mask Writer).

Up until now, aspects of the inventive concept have been described in connection with the reticle pattern, i.e., the pattern whose image corresponds to the circuit pattern that is to be transferred to a wafer in each of several shots, for example. Therefore, it is equally applicable to describe an aspect of the inventive concept in terms of the shot or shots.

In a conventional method, if a stack structure of an upper portion of a shot is different from that of a lower portion of the shot or a boundary exists between a cell region and a peripheral circuit region of the shot, there is a high probability that a peripheral circuit formed by the shot will be defective, there is a relatively small process margin due to the step difference, and the focal plane may be tilted by the leveling operation due to a step difference in the upper and lower portions of the shot. Accordingly, a focus error may occur in executing the shot.

In contrast, according to a method for use in fabricating a semiconductor device according to the inventive concept, upper and lower portions of a shot may have the same stack structure. That is, stack structures of upper and lower portions of the shot may be identical equal to each other, e.g., the upper and lower portions of the shot may comprise cell arrays and peripheral circuits disposed (symmetrically) on opposite sides of a boundary, respectively, thereby reducing the probability that the fabricating of the peripheral circuits will fail, allowing for a high process margin, and mitigating problems such a tilt during a leveling operation.

In another example, a top portion and a bottom portion of the shot of the inventive concept may be a cell array and a peripheral circuit, respectively. Here, the cell stack structure and the peripheral circuit stack structure may be different from each other. Also, the shot of the inventive concept may be configured of chips whose peripheral and cell areas face each other. If the same stack structures are disposed at both portions of the shot, it may be possible to solve problems of focus error and overlay due to a step difference during the leveling operation.

Also, if the shot is configured such that cell and peripheral areas face each other, a scribe lane pattern between a cell stack and a peripheral stack may not exist other than at locations between chips. A decrease in process margin may be minimized by minimizing the number of scribe lanes between cell and peripheral stacks.

In addition, it may be possible to minimize dislocation due to stress occurring at a cell stack by forming a TEG pattern in the form of a cell stack or an alignment key in a scribe lane pattern between cell areas and/or by forming a TEG pattern in the form of a peripheral stack or an alignment key in a scribe lane pattern between peripheral areas. A shot having a configuration formed according to the inventive concept may improve productivity in the fabricating of chips from a wafer.

Although the inventive concept has been described with reference to various examples, it will be apparent to those skilled in the art that various changes and modifications may be made to such examples without departing from the spirit and scope of the inventive concept. Therefore, it should be understood that the above-described examples are not limiting, but merely illustrative of the inventive concept.

What is claimed is:

1. A reticle for use in a lithographic exposure process, comprising:
a substrate and a reticle pattern borne by the substrate,
wherein the reticle pattern comprises patterns of core areas of at least two chips, patterns of peripheral areas of the at least two chips, and a scribe lane pattern separating the patterns of the chips from one another,
wherein the patterns of the core areas of two of the chips are disposed directly across from each other on opposite sides of the scribe lane pattern and/or the patterns of the peripheral areas of two of the chips are disposed on opposite sides of a scribe lane as disposed directly across from each other.

2. The reticle of claim 1, wherein the pattern of each of the core areas comprises a pattern of a cell array and an address decoder, the patterns of the address decoders being disposed on opposite sides of the cell array.

3. The reticle of claim 2, wherein the pattern of the cell array comprises a pattern of a V-NAND (vertical NAND Flash Memory) block.

4. The reticle of claim 2, wherein the pattern of the cell array comprises the pattern of a PBiCS (Pipe-shaped bit cost scalable) block.

5. The reticle of claim 1, wherein the pattern of each of the peripheral areas comprises the pattern of a page buffer.

6. The reticle of claim 1, wherein with respect to the patterns of each of at least one pair of the chips, the patterns of the core areas or the patterns of the peripheral areas have point symmetry with respect to a point in the scribe lane pattern.

7. The reticle of claim 1, wherein the patterns of two of the chips are symmetrical with respect to a first linear scribe lane of the scribe lane pattern.

8. The reticle of claim 7, wherein patterns of at least two different chips are disposed to have line symmetry on the basis of a second scribe lane pattern, and wherein the second scribe lane pattern is different from the first scribe lane pattern.

9. The reticle of claim 1, wherein the scribe lane pattern has a test element group and an alignment key pattern interposed between the patterns of two of the chips.

10. The reticle of claim 9, wherein the scribe lane pattern has a pattern of a linear first scribe lane interposed between the patterns of peripheral areas of two of the chips, the pattern of the first scribe lane including a pattern of a test element group for the peripheral areas.

11. The reticle forming method of claim 10, wherein the scribe lane pattern also has a pattern of a second scribe lane interposed between the patterns of the core areas of two of the chips, the pattern of the second scribe lane including a pattern of a test element group for cells of the core areas.

12. The reticle of claim 1, wherein the reticle pattern comprises patterns of eight chips.

13. The reticle of claim 1, wherein the pattern of each of the at least two chips is a pattern of a 2-mat structure.

14. A method of manufacturing a reticle, comprising:
forming a photoresist layer on a substrate;
forming a photoresist pattern by exposing and developing the photoresist layer; and
carrying out an etch process using the photoresist pattern as an etch mask,
wherein the forming of the photoresist pattern and the etch process form a reticle pattern comprising patterns of core areas of at least two chips, patterns of peripheral areas of the at least two chips, and a scribe lane pattern separating the patterns of the chips from one another,
wherein the patterns of the core areas of two of the chips are disposed directly across from each other on opposite sides of the scribe lane pattern and/or the patterns of the peripheral areas of two of the chips are disposed on opposite sides of a scribe lane as disposed directly across from each other.

15. The method of claim 14, wherein the substrate is transparent, and further comprising forming an opaque mask layer on the substrate, and wherein the photoresist layer is formed on the mask layer, and the etch process comprises etching the mask layer using the photoresist pattern as an etch mask.

16. An exposure apparatus comprising:
a light source;
a reticle comprising a substrate and having a reticle pattern borne by the substrate,
the reticle pattern includes patterns of core areas of at least two chips, patterns of peripheral areas of the at least two chips, and a scribe lane pattern separating the patterns of the chips from one another,
the patterns of the core areas of two of the chips are disposed directly across from each other on opposite sides of the scribe lane pattern and/or the patterns of the peripheral areas of two of the chips are disposed on opposite sides of a scribe lane as disposed directly across from each other, and
the reticle being supported in the exposure apparatus so as to be illuminated with light emitted from the light source, and thereby transmit an image of the reticle pattern;
reduction-projection optics that reduces the size of the image of the reticle pattern transmitted by the reticle and projects the reduced image of the reticle pattern along an optical axis; and
a wafer stage configured to support a wafer in the path of the optical axis such that a layer on the wafer can be exposed to the image of the reticle pattern projected by the reduction-projection optics.

17. The exposure apparatus of claim 16, wherein, in the reticle pattern, the pattern of each of the core areas comprises a pattern of a cell array and an address decoder, the patterns of the address decoders being disposed on opposite sides of the cell array.

18. The exposure apparatus of claim 16, wherein, in the reticle pattern, the pattern of each of the peripheral areas comprises the pattern of a page buffer.

19. The exposure apparatus of claim 16, wherein, in the reticle pattern, the patterns of the core areas and/or the patterns of the peripheral areas are symmetrical with respect to a linear section of the scribe lane pattern.

20. The exposure apparatus of claim 16, wherein, in the reticle pattern, the patterns of two of the chips are symmetrical with respect to a first linear scribe lane of the scribe lane pattern.
